(19) United States
(12) Patent Application Publication
(10) Pub. No.: US 2026/0173707 A1
(43) Pub. Date: Jun. 18, 2026

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Zhenglong YAN, Beijing (CN); Yanyang SHANG, Beijing (CN); Zhu WANG, Beijing (CN)

(21) Appl. No.: 18/710,587

(22) PCT Filed: Apr. 19, 2023
(86) PCT No.: PCT/CN2023/089125

§ 371 Date: May 15, 2024

(30) Foreign Application Priority Data
Jun. 23, 2022 (CN) 202210723269.7

(51) Int. Cl. H10K 59/40; H10K 59/131

(52) U.S. Cl. CPC H10K 59/40; H10K 59/131

(57) ABSTRACT

Disclosed in embodiments of the present disclosure are a display panel and a display device. A first lead, located in a bending region, of a touch lead uses a second metal layer for routing, and a second lead, located in a binding region, of the touch lead uses a third metal layer for routing, so that no touch structure, i.e., no organic insulating layer nonresistant to high temperature, is present in the binding region and the bending region. That is, the organic insulating layer in the binding region and the bending region can be removed in a large area by forming a large groove, and the connection relationship of the touch lead is not affected.

### CROSS-REFERENCE TO RELATED APPLICATION

The disclosure is a National Stage of International Application No. PCT/CN2023/089125, filed on Apr. 19, 2023, which claims the priority of Chinese Patent Application No. 202210723269.7, filed with the China National Intellectual Property Administration on Jun. 23, 2022 and entitled “DISPLAY PANEL AND DISPLAY DEVICE”, which is incorporated in its entirety herein by reference.

### TECHNICAL FIELD

The disclosure relates to the technical field of touch display, and in particular, relates to a display panel and a display device.

### BACKGROUND

With the ongoing development of electronic products, active matrix organic light emitting diode (AMOLED) display devices have been used in a wide range because of a full screen, a narrow bezel, a high resolution, rollable wear, foldability, etc. A lighter and thinner display device can be manufactured through a flexible multi-layer on cell (FMLOC) technology of manufacturing a touch structure directly on an encapsulation layer of an organic light emitting diode (OLED) display panel, and this technology can be applied to foldable and rollable OLED display devices.

### SUMMARY

A display panel and a display device are provided in embodiments of the disclosure, to solve the problems in the related art that owing to the weak adhesion of an organic insulation layer of a touch structure, a peeling phenomenon is likely to be generated in a binding region.

A display panel is provided in an embodiment of the disclosure. The display panel includes: a display region, a binding region on one side of the display region, and a bending region between the display region and the binding region. The display panel includes: a base substrate; a first metal layer on the base substrate; a second metal layer on one side, facing away from the base substrate, of the first metal layer; a third metal layer on one side, facing away from the base substrate, of the second metal layer; and a touch structure on one side, facing away from the base substrate, of the third metal layer. The touch structure includes organic insulation layers and touch electrode layers that are stacked, and a touch lead electrically connected to the touch electrode layer; the touch lead extends from the display region to the binding region; the touch lead includes a first lead in the bending region and a second lead in the binding region, the first lead is in the second metal layer, and the second lead is in the third metal layer; and an orthographic projection of the organic insulation layer on the base substrate does not overlap orthographic projections of the binding region and the bending region on the base substrate.

Optionally, the above display panel according to the embodiment of the disclosure further includes: a first planarization layer between the third metal layer and the touch structure, and a second planarization layer between the second metal layer and the third metal layer; and the touch lead further includes a third lead in the display region, the third lead is electrically connected to the first lead through a via hole penetrating the first planarization layer and the second planarization layer, and the first lead is electrically connected to the second lead through a via hole penetrating the second planarization layer.

Optionally, the above display panel according to the embodiment of the disclosure further includes: a transition region between the display region and the bending region, and the third lead extends to the transition region to be electrically connected to the first lead through the via hole penetrating the first planarization layer and the second planarization layer.

Optionally, the above display panel according to the embodiment of the disclosure further includes: a third planarization layer between the first metal layer and the second metal layer, a high-voltage power line, and a low-voltage power line. The high-voltage power line includes a first conductive structure and a second conductive structure in the binding region, the first conductive structure is in the first metal layer, the second conductive structure is in the second metal layer, and the first conductive structure is electrically connected to the second conductive structure through a via hole penetrating the third planarization layer; and the low-voltage power line includes a third conductive structure and a fourth conductive structure in the binding region, the third conductive structure is in the first metal layer, the third conductive structure is arranged spaced from the first conductive structure, the fourth conductive structure is in the second metal layer, the fourth conductive structure is arranged spaced from the second conductive structure, and the third conductive structure is electrically connected to the fourth conductive structure through the via hole penetrating the third planarization layer.

Optionally, in the above display panel according to the embodiment of the disclosure, the high-voltage power line further includes a fifth conductive structure in the binding region, the fifth conductive structure is in the third metal layer, and the fifth conductive structure is electrically connected to the second conductive structure through the via hole penetrating the second planarization layer; the low-voltage power line further includes a sixth conductive structure in the binding region, the sixth conductive structure is in the third metal layer, the sixth conductive structure is arranged spaced from the fifth conductive structure, and the sixth conductive structure is electrically connected to the fourth conductive structure through the via hole penetrating the second planarization layer; and the second lead is insulated from the fifth conductive structure and the sixth conductive structure.

Optionally, in the above display panel according to the embodiment of the disclosure, the sixth conductive structure includes two conductive sub-structures arranged spaced from each other, and the second lead is located between the two conductive sub-structures.

Optionally, in the above display panel according to the embodiment of the disclosure, the organic insulation layers include a first organic insulation layer and a second organic insulation layer that are stacked, and the touch electrode layers include a first touch electrode layer between the first organic insulation layer and the second organic insulation layer, and a second touch electrode layer on one side, facing away from the base substrate, of the second organic insulation layer; and the third lead includes a first sub-lead and a second sub-lead that are electrically connected to each other, the first sub-lead is in the first touch electrode layer, the second sub-lead is in the second touch electrode layer, and the first sub-lead is electrically connected to the first lead through the via hole penetrating the first planarization layer and the second planarization layer.

Optionally, the above display panel according to the embodiment of the disclosure further includes: a protective layer on one side, facing away from the base substrate, of the second touch electrode layer; a material of the protective layer is the same as a material of the organic insulation layers; an orthographic projection of the protective layer on the base substrate covers the base substrate; and the protective layer is in direct contact with the second lead.

Optionally, the above display panel according to the embodiment of the disclosure further includes: a protective layer on one side, facing away from the base substrate, of the second touch electrode layer; a material of the protective layer is the same as a material of the organic insulation layers; an orthographic projection of the first planarization layer on the base substrate covers the base substrate; and an orthographic projection of the protective layer on the base substrate does not overlap the orthographic projections of the binding region and the bending region on the base substrate.

Correspondingly, a display device is further provided in an embodiment of the disclosure. The display device includes the any display panel described above according to the embodiments of the disclosure.

The embodiments of the disclosure have the beneficial effects as follows: in the display panel and the display device according to the embodiments of the disclosure, the first lead, located in the bending region, of the touch lead is routed in the second metal layer; and the second lead, located in the binding region, of the touch lead is routed in the third metal layer. In this way, no touch structure, i.e., no organic insulation layer nonresistant to a high temperature, is arranged in the binding region and the bending region. In other words, the organic insulation layer may be removed from the binding region and the bending region in a large area through a large groove without affecting a connection relation of the touch lead. Therefore, when a binding process is performed in the binding region, the phenomenon that the organic insulation layer is peeled off due to a high-temperature environment can be avoided, so that the yield of display products can be improved.

### BRIEF DESCRIPTION OF FIGURES

FIG. 1 is a schematic structural diagram of a top view of a display panel according to an embodiment of the disclosure.

FIG. 2 is a schematic structural diagram of a section of a sub-pixel in FIG. 1.

FIG. 3 is a schematic structural diagram of a section in a direction MM′ in FIG. 1.

FIG. 4 is a schematic structural diagram of a section in a direction FF′ in FIG. 1 in the related art.

FIG. 5 is a schematic structural diagram of a section in a direction FF′ in FIG. 1 according to an embodiment of the disclosure.

FIG. 6 is another schematic structural diagram of a section in a direction FF′ in FIG. 1 according to an embodiment of the disclosure.

FIG. 7 is a schematic structural diagram of a top view of a high-voltage power line VDD and a low-voltage power line VSS in a binding region.

FIG. 8 is a schematic structural diagram of a top view of VDD, VSS, and a second lead in a binding region.

FIG. 9 is another schematic structural diagram of a top view of VDD, VSS, and a second lead in a binding region.

### DETAILED DESCRIPTION

In order to make objectives, technical solutions, and advantages of the disclosure clearer, the particular implementations of the display panel and the display device according to embodiments of the disclosure are described in detail below in conjunction with the accompanying drawings. It should be understood that preferred embodiments described below are merely used to describe and explain the disclosure, and are not intended to limit the disclosure. Moreover, the embodiments in the disclosure and features in the embodiments can be combined mutually without conflict.

A thickness, a size, and a shape of each film layer in the accompanying drawings do not reflect a real ratio of the display panel, and are merely intended to illustrate the contents of the disclosure.

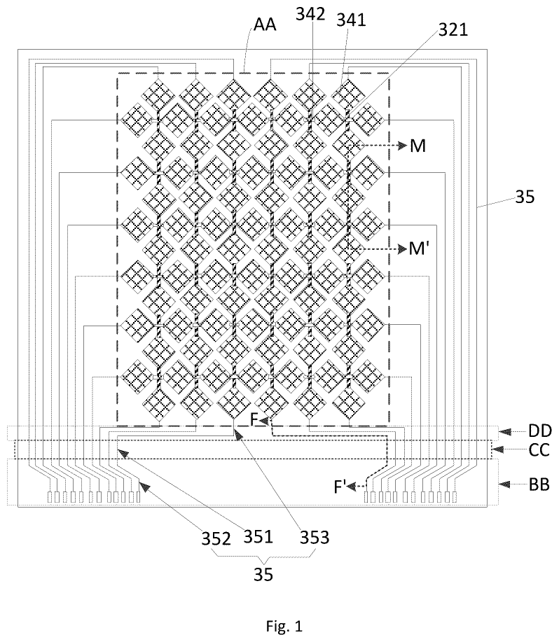

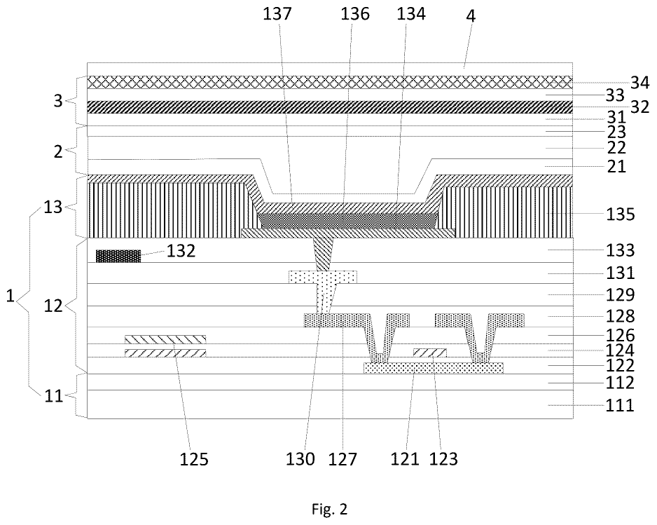

FIG. 1 is a schematic diagram of a planar structure of an organic light emitting diode (OLED) display panel provided with touch electrodes. As shown in FIGS. 1 and 2, the display panel includes: a display region AA, a binding region BB on one side of the display region AA, and a bending region CC between the display region AA and the binding region BB. The display region AA generally includes a plurality of light emitting sub-pixels. FIG. 2 is a schematic diagram of a section of a light emitting sub-pixel in FIG. 1. As shown in FIG. 2, the display panel includes a display substrate 1, an encapsulation layer 2 configured to encapsulate the display substrate 1, a touch structure 3 on the encapsulation layer 2, and a protective layer 4 (an organic insulation layer) on the touch structure 3. The encapsulation layer 2 may include a first inorganic layer 21, an organic layer 22, and a second inorganic layer 23 that are stacked on the display substrate 1. The touch structure 3 may be manufactured directly on the encapsulation layer 2 through a flexible multi-layer on cell (FMLOC) technology. By using the FMLOC technology, a lighter and thinner touch panel can be manufactured. This technology can be applied to foldable and rollable OLED display devices.

As shown in FIG. 2, the display substrate 1 includes a base substrate 11, and a drive circuit 12 and a light emitting device layer 13 that are stacked on the base substrate 11. Optionally, the base substrate 11 may include a polyimide layer 111 and a buffer layer 112 that are sequentially stacked. The drive circuit 12 may include an active layer 121, a first gate insulation layer 122, a first gate metal layer 123, a second gate insulation layer 124, a second gate metal layer 125, an interlayer dielectric layer 126, a first metal layer (a first source-drain metal layer (SD1)) 127, a passivation layer 128, a first planarization layer 133, a second metal layer (a second source-drain metal layer (SD2)) 130, a second planarization layer 131, a third metal layer (a third source-drain metal layer (SD3)) 132, and a third planarization layer 129 that are sequentially stacked on the base substrate 11. The light emitting device layer 13 may include an anode layer 134, a pixel defining layer 135, a light emitting function layer 136, and a cathode layer 137 that are sequentially stacked on the drive circuit 12. The anode layer 134 may be electrically connected to the first metal layer 127 through the second metal layer 130.

Specifically, the first metal layer 127 is generally provided with a source, a drain, a data line, etc. The second metal layer 130 is generally configured as an intermediate electrode overlapping the anode layer 134 and the drain. The third metal layer 132 is manufactured based on a fanout in AA (FIAA) technology used for a project of narrow-bezel products. Through such a technology, one third metal layer 132 and one third planarization layer 129 are added. The third metal layer 132 is mainly configured for data signal line pulling in a fanout region, to realize the narrow bezel design for the lower bezel.

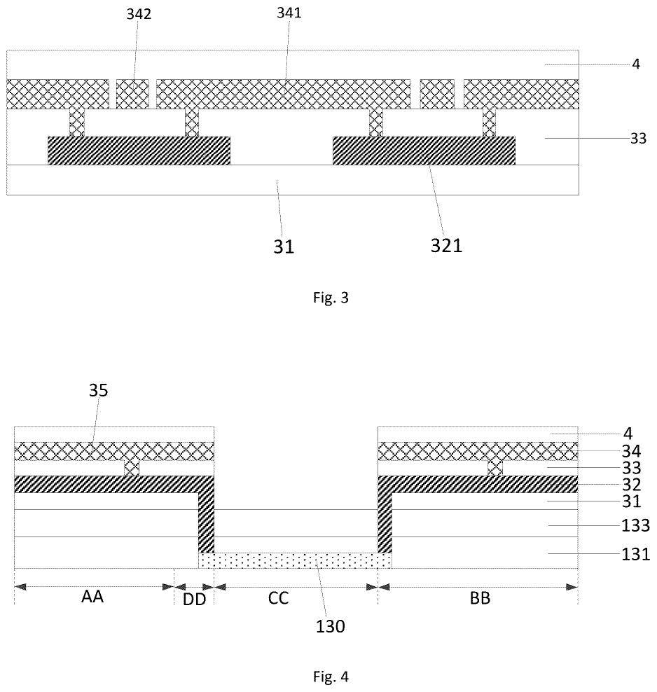

As shown in FIGS. 1 and 2, a touch structure 3 is formed on the encapsulation layer 2 of the display panel. The touch structure 3 includes a first organic insulation layer 31, a first touch electrode layer 32, a second organic insulation layer 33, and a second touch electrode layer 34 that are stacked. Optionally, FIG. 3 is a schematic diagram of a section in a direction MM′ in FIG. 1; and as shown in FIGS. 1 and 3, the first touch electrode layer 32 may include a plurality of bridging electrodes 321, and the second touch electrode layer 34 may include a plurality of touch electrodes 341. Some touch electrodes 341 are directly electrically connected through connection portions 342 in the second touch electrode layer 34; and the remaining touch electrodes 341 are electrically connected through the bridging electrodes 321 in the first touch electrode layer 32. Therefore, Tx touch electrodes and Rx touch electrodes are acquired.

As shown in FIG. 1, the touch structure 3 further includes a touch lead 35 electrically connected to the touch electrodes 341, and the touch lead 35 extends from the display region AA to the binding region BB. FIG. 4 is a schematic diagram of a section of a touch lead 35 in a direction FF′ in FIG. 1 in the related art. As shown in FIG. 4, a portion, located in the display region AA, of the touch lead 35 is generally configured as two layers of metal wires (the two layers of wires are located in the first touch electrode layer 32 and the second touch electrode layer 34 respectively and electrically connected to reduce the resistance); a portion, located in the bending region CC, of the touch lead 35 generally jumps to the second metal layer 130; and a portion, located in the binding region BB, of the touch lead 35 jumps to the first touch electrode layer 32 and the second touch electrode layer 34. In other words, the portion, located in the binding region BB, of the touch lead 35 is also configured as two layers of wires (the two layers of wires are located in the first touch electrode layer 32 and the second touch electrode layer 34 respectively and electrically connected to reduce the resistance). The organic insulation layers (31, 33, and 4) are respectively arranged below the first touch electrode layer 32, between the first touch electrode layer 32 and the second touch electrode layer 34, and above the second touch electrode layer 34. Since a manufacturing process of the touch structure 3 is performed after an encapsulation process, and a material of the encapsulation layer 2 is not resistant to a high temperature, the manufacturing process of the touch structure 3 may be performed in a low-temperature environment only. For example, only a low-temperature process at 85° C. may be employed. However, an organic insulation layer material that is adaptable to the low-temperature process is a negative optical adhesive. Therefore, the organic insulation layers (31, 33, and 4) are made of a low-temperature negative optical adhesive. However, after the touch structure 3 is manufactured, since a high-temperature (such as 170° C.) process is required to perform a binding process, the binding region BB has a high temperature during binding. Owing to the weak adhesion of the low-temperature negative optical adhesive, the organic insulation layers (31, 33, and 4) nonresistant to the high temperature in the binding region BB will be peeled off during pressing under the action of the high temperature, which greatly reduces the yield of the display products.

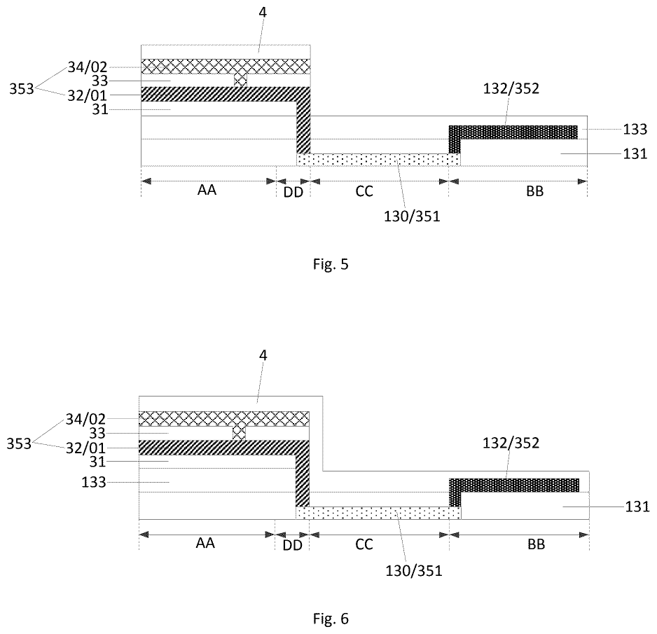

In order to solve the above technical problem, a display panel is provided in the embodiments of the disclosure. FIGS. 5 and 6 are schematic diagrams of sections of the touch lead 35 in a direction FF′ in FIG. 1 according to the embodiments of the disclosure. As shown in FIGS. 1-3, 5, and 6, the display panel includes a display region AA, a binding region BB on one side of the display region AA, and a bending region CC between the display region AA and the binding region BB. The display panel includes: a base substrate 11; a first metal layer 127 on the base substrate 11; a second metal layer 130 on one side, facing away from the base substrate 11, of the first metal layer 127; a third metal layer 132 on one side, facing away from the base substrate 11, of the second metal layer 130; and a touch structure 3 on one side, facing away from the base substrate 11, of the third metal layer 132. The touch structure 3 includes organic insulation layers (31 and 33) and touch electrode layer (32 and 34) that are stacked, and touch leads 35 electrically connected to the touch electrode layers (32 and 34); and the touch lead 35 extends from the display region AA to the binding region BB. The touch lead 35 includes a first lead 351 in the bending region CC and a second lead 352 in the binding region BB, the first lead 351 is located in the second metal layer 130, and the second lead 352 is located in the third metal layer 132. Orthographic projections of the organic insulation layers (31 and 33) on the base substrate 11 do not overlap orthographic projections of the binding region BB and the bending region CC on the base substrate 11.

In the above display panel according to the embodiments of the disclosure, the first lead 351, located in the bending region CC, of the touch lead 35 is routed in the second metal layer 130; and the second lead 352, located in the binding region BB, of the touch lead 35 is routed in the third metal layer 132. In this way, no touch structure 3 (i.e., no organic insulation layers (31 and 33) nonresistant to a high temperature) is provided in the binding region BB and the bending region CC. In other words, the organic insulation layers (31 and 33) may be removed from the binding region BB and the bending region CC in a large area through a large groove without affecting a connection relation of the touch lead 35. Therefore, when a binding process is performed in the binding region BB, the phenomenon that the organic insulation layers (31 and 33) are peeled off due to a high-temperature environment can be avoided, so that the yield of the display products can be improved. In addition, in the embodiments of the disclosure, the second lead 352, located in the binding region BB, of the touch lead 35 is routed in the third metal layer 132. In this way, the organic insulation layers (31 and 33) are obviously removed from the binding region BB and the bending region CC directly on the basis of a narrow-bezel solution. Moreover, it is not required to add a metal film layer separately to manufacture the second lead 352 in the binding region BB.

Optionally, as shown in FIGS. 2, 5, and 6, the first metal layer 127 may be an SD1 layer, the second metal layer 130 may be an SD2 layer, and the third metal layer 132 may be an SD3 layer. Specifically, the SD1 layer is generally provided with a source, a drain, a data line, etc.; the SD2 layer is generally provided with an intermediate electrode overlapping an anode layer and the drain; and the SD3 layer is manufactured based on the FIAA technology used for a project of narrow-bezel products. Through such a technology, one SD3 layer and one third planarization layer (described later) are added. The SD3 layer is mainly configured for data signal line pulling in a fanout region (the binding region, the bending region, and a transition region). In other words, the data line in the SD1 layer jumps to the SD3 layer through a via hole. This reduces the area occupied by signal lines in the SD1 layer in the fanout region, realizing the narrow bezel design for the lower bezel.

During specific implementation, as shown in FIGS. 1, 2, 5, and 6, the above display panel according to the embodiments of the disclosure further includes: a first planarization layer 133 between the third metal layer 132 and the touch structure 3, and a second planarization layer 131 between the second metal layer 130 and the third metal layer 132; and
the touch lead 35 further includes a third lead 353 in the display region AA, the third lead 353 is electrically connected to the first lead 351 through a via hole penetrating the first planarization layer 133 and the second planarization layer 131, and the first lead 351 is electrically connected to the second lead 352 through a via hole penetrating the second planarization layer 131.

During specific implementation, as shown in FIGS. 1, 2, 5, and 6, the above display panel according to the embodiments of the disclosure further includes: a transition region DD between the display region AA and the bending region CC, and the third lead 353 extends to the transition region DD to be electrically connected to the first lead 351 through the via hole penetrating the first planarization layer 133 and the second planarization layer 131.

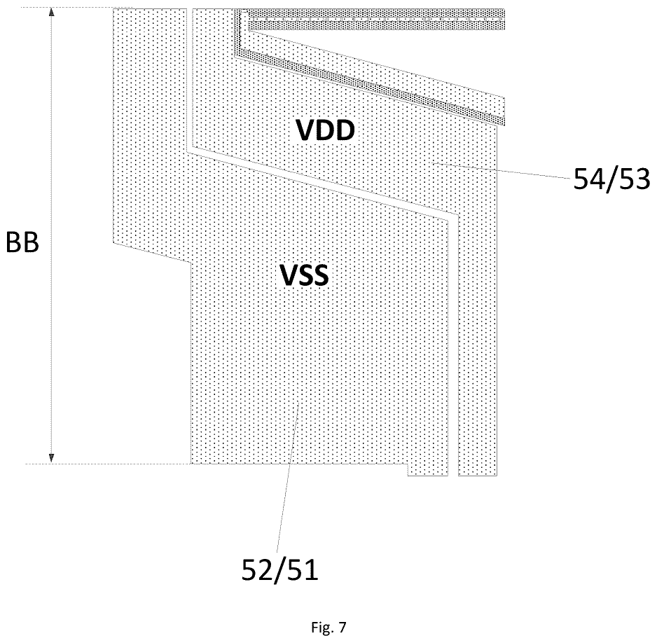

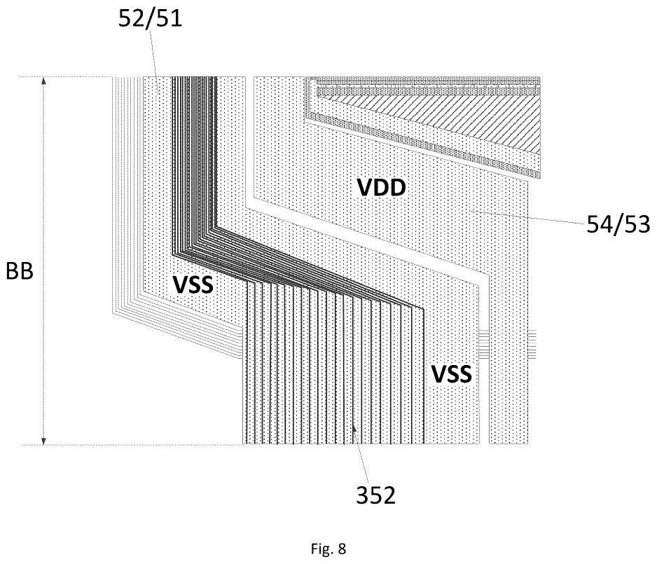

During specific implementation, FIGS. 7 and 8 are schematic diagrams of a top view of the binding region BB in FIG. 1, and as shown in FIGS. 1, 2, 7, and 8, the above display panel according to the embodiments of the disclosure further includes: a third planarization layer 129 between the first metal layer 127 and the second metal layer 130, a high-voltage power line VDD and a low-voltage power line VSS.

The high-voltage power line VDD includes a first conductive structure 51 and a second conductive structure 52 in the binding region BB, the first conductive structure 51 is located in the first metal layer 127 in FIG. 2, the second conductive structure 52 is located in the second metal layer 130 in FIG. 2, and the first conductive structure 51 is electrically connected to the second conductive structure 52 through a via hole penetrating the third planarization layer 129. It should be noted that the first conductive structure 51 and the second conductive structure 52 electrically connected to each other are arranged in the binding region BB, to reduce the resistance of the high-voltage power line VDD. The first conductive structure 51 and the second conductive structure 52 have the same pattern, and the first conductive structure 51 is covered by the pattern of the second conductive structure 52.

The low-voltage power line VSS includes a third conductive structure 53 and a fourth conductive structure 54 in the binding region BB, the third conductive structure 53 is located in the first metal layer 127 in FIG. 2, the third conductive structure 53 is arranged spaced from the first conductive structure 51, the fourth conductive structure 54 is located in the second metal layer 130 in FIG. 2, the fourth conductive structure 54 is arranged spaced from the second conductive structure 52, and the third conductive structure 53 is electrically connected to the fourth conductive structure 54 through the via hole penetrating the third planarization layer 129. It should be noted that the third conductive structure 53 and the fourth conductive structure 54 electrically connected to each other are arranged in the binding region BB, to reduce the resistance of the low-voltage power line VSS. The third conductive structure 53 and the fourth conductive structure 54 have the same pattern, and the third conductive structure 53 is covered by the pattern of the fourth conductive structure 54.

Specifically, as shown in FIGS. 7 and 8, the high-voltage power line VDD and the low-voltage power line VSS in the embodiments of the disclosure may be provided with the conductive structures for reducing the resistance only in the first metal layer 127 and the second metal layer 130 in the binding region BB. The second lead 352, located in the binding region BB, of the touch lead 35 is arranged in the third metal layer 132; and the third planarization layer 129 is arranged between the third metal layer 132 and the second metal layer 130. Therefore, the second lead 352 will not affect the design of the conductive structures of the high-voltage power line VDD and the low-voltage power line VSS.

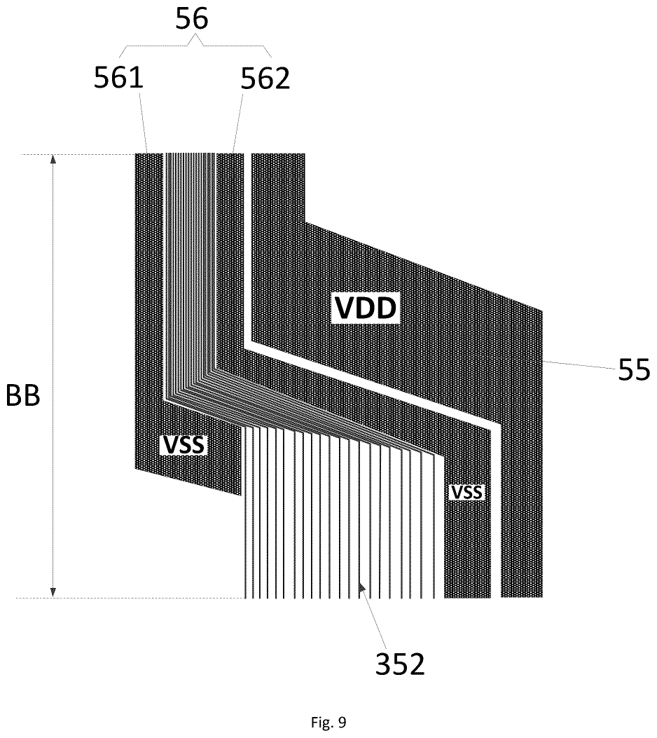

During specific implementation, in the above display panel according to the embodiments of the disclosure, as shown in FIG. 9, the high-voltage power line VDD further includes a fifth conductive structure 55 in the binding region BB, the fifth conductive structure 55 is located in the third metal layer 132 in FIG. 2, and the fifth conductive structure 55 is electrically connected to the second conductive structure 52 through the via hole penetrating through the second planarization layer 131. It should be noted that the first conductive structure 51, the second conductive structure 52, and the fifth conductive structure 55 electrically connected to one another are arranged in the binding region BB, to further reduce the resistance of the high-voltage power line VDD. The first conductive structure 51, the second conductive structure 52, and the fifth conductive structure 55 have the same pattern; and the first conductive structure 51 and the second conductive structure 52 are covered by the pattern of the fifth conductive structure 55.

The low-voltage power line VSS further includes a sixth conductive structure 56 in the binding region BB, the sixth conductive structure 56 is located in the third metal layer 132 in FIG. 2, the sixth conductive structure 56 is arranged spaced from the fifth conductive structure 55, and the sixth conductive structure 56 is electrically connected to the fourth conductive structure 54 through the via hole penetrating the second planarization layer 131. It should be noted that the third conductive structure 53, the fourth conductive structure 54, and the sixth conductive structure 56 electrically connected to one another are arranged in the binding region BB, to further reduce the resistance of the low-voltage power line VSS. The third conductive structure 53 and the fourth conductive structure 54 have the same pattern, and the sixth conductive structure 56 covers parts of the third conductive structure 53 and the fourth conductive structure 54. FIG. 9 shows the fifth conductive structure 55 and the sixth conductive structure 56 in the third metal layer 132 only. The first conductive structure 51, the second conductive structure 52, the third conductive structure 53, and the fourth conductive structure 54 have the same pattern as that in FIG. 7.

The second lead 352 is insulated from the fifth conductive structure 55 and the sixth conductive structure 56. In this way, the fifth conductive structure 55, the sixth conductive structure 56, and the second lead 352 may not affect one another.

During specific implementation, in the above display panel according to the embodiments of the disclosure, as shown in FIG. 9, the sixth conductive structure 56 includes two conductive sub-structures (561 and 562) arranged spaced from each other, and the second lead 352 may be located between the two conductive sub-structures (561 and 562). In other words, an orthographic projection of the second lead 352 on the base substrate 11 does not overlap orthographic projections of the two conductive sub-structures (561 and 562) on the base substrate 11. Specifically, the two conductive sub-structures are electrically connected to the fourth conductive structure 54. The second lead 352, located in the binding region BB, of the touch lead 35 is arranged in the third metal layer 132; the high-voltage power line VDD further includes the fifth conductive structure 55 located in the third metal layer 132 in the binding region BB; and the low-voltage power line VSS further includes the sixth conductive structure 56 located in the third metal layer 132 in the binding region BB. In this way, the high-voltage power line VDD, the low-voltage power line VSS and the second lead 352 will not affect one another on the basis of further reducing the resistance of the high-voltage power line VDD and the low-voltage power line VSS.

During specific implementation, in the above display panel according to the embodiments of the disclosure, as shown in FIGS. 1, 2, 5, and 6, the organic insulation layers (31 and 33) include a first organic insulation layer 31 and a second organic insulation layer 33 that are stacked; and the touch electrode layers (32 and 34) include a first touch electrode layer 32 between the first organic insulation layer 31 and the second organic insulation layer 33, and a second touch electrode layer 34 on one side, facing away from the base substrate 11, of the second organic insulation layer 33.

The third lead 353 includes a first sub-lead 01 and a second sub-lead 02 electrically connected to each other, the first sub-lead 01 is located in the first touch electrode layer 32, the second sub-lead 02 is located in the second touch electrode layer 34, and the first sub-lead 01 is electrically connected to the first lead 351 through the via hole penetrating the first planarization layer 133 and the second planarization layer 131. In this way, the third lead 353 is configured as two layers of metal wires, to reduce the resistance of the touch lead 35.

During specific implementation, as shown in FIGS. 2 and 6, the above display panel according to the embodiments of the disclosure further includes a protective layer 4 on one side, facing away from the base substrate 11, of the second touch electrode layer 34; a material of the protective layer 4 is the same as a material of the organic insulation layers (31 and 33); an orthographic projection of the protective layer 4 on the base substrate 11 covers the base substrate 11; and the protective layer 4 is in direct contact with the second lead 352. In this way, the protective layer 4 may protect touch electrodes in the display region AA and the second lead 352 in the binding region BB. Moreover, portions, in the binding region BB and the bending region CC, of the first planarization layer 133 may be completely removed, so that bending performance is improved.

During specific implementation, as shown in FIGS. 2 and 5, the above display panel according to the embodiments of the disclosure further includes a protective layer 4 on one side, facing away from the base substrate 11, of the second touch electrode layer 34; a material of the protective layer 4 is the same as a material of the organic insulation layers (31 and 33); an orthographic projection of the first planarization layer 133 on the base substrate 11 covers the base substrate 11; and an orthographic projection of the protective layer on the base substrate 11 does not overlap orthographic projections of the binding region BB and the bending region CC on the base substrate. Since a material of the first planarization layer 133 may be generally resistant to a high temperature and thus is stable, the first planarization layer 133 that is stable may be directly used as the protective layer in the binding region BB to further improve the yield of the display products.

It should be noted that FIGS. 5 and 6 in the embodiments of the disclosure are merely to illustrate that the first lead 351, located in the bending region CC, of the touch lead 35 is routed in the second metal layer 130; and the second lead 352 in the binding region BB is routed in the third metal layer 132. No touch structure, i.e., no organic insulation layers nonresistant to the high temperature, is provided in the binding region BB and the bending region CC. In other words, the organic insulation layers may be removed from the binding region BB and the bending region CC in a large area through the large groove, and the organic insulation layers can be prevented from being peeled off during binding. Certainly, as shown in FIGS. 5 and 6, the above display panel may further include other required film layers in the binding region BB and the bending region CC.

Based on the same inventive concept, a display device is further provided in embodiments of the disclosure. The display device includes the above display panel according to the embodiments of the disclosure. The display device may be any product or component with a display function, such as a mobile phone, a tablet computer, a television, a display, a notebook computer, a digital photo frame, and a navigator. Reference may be made to the embodiments of the above display panel for the implementation of the display device, the repetitions of which will not described in detail.

In the display panel and the display device according to the embodiments of the disclosure, the first lead, located in the bending region, of the touch lead is routed in the second metal layer; and the second lead, located in the binding region, of the touch lead is routed in the third metal layer. In this way, no touch structure (i.e., no organic insulation layers nonresistant to the high temperature) is arranged in the binding region and the bending region. In other words, the organic insulation layers may be removed from the binding region and the bending region in a large area through the large groove without affecting the connection relation of the touch lead. Therefore, when the binding process is performed in the binding region, the phenomenon that the organic insulation layers are peeled off due to the high-temperature environment can be avoided, so that the yield of the display products can be improved. In addition, in the embodiments of the disclosure, the second lead, located in the binding region, of the touch lead is routed in the third metal layer. In this way, the organic insulation layers are obviously removed from the binding region and the bending region directly on the basis of the narrow-bezel solution, and it is not required to add the metal film layer separately to manufacture the second lead in the binding region.

Obviously, a person skilled in the art can make various changes and variations to the disclosure without departing from the spirit and scope of the disclosure. In this way, the disclosure is also intended to encompass these changes and variations to the disclosure if these changes and variations fall within the scope of the claims of the disclosure and their equivalents.

1. A display panel, comprising: a display region, a binding region on one side of the display region, and a bending region between the display region and the binding region;
wherein the display panel comprises:
a base substrate;
a first metal layer on the base substrate;
a second metal layer on one side, facing away from the base substrate, of the first metal layer;
a third metal layer on one side, facing away from the base substrate, of the second metal layer; and
a touch structure on one side, facing away from the base substrate, of the third metal layer;
wherein the touch structure comprises organic insulation layers and touch electrode layers that are stacked, and a touch lead electrically connected to the touch electrode layer;
the touch lead extends from the display region to the binding region;
the touch lead comprises a first lead in the bending region and a second lead in the binding region, the first lead is in the second metal layer, and the second lead is in the third metal layer; and
an orthographic projection of the organic insulation layer on the base substrate does not overlap orthographic projections of the binding region and the bending region on the base substrate.

2. The display panel according to claim 1, further comprising: a first planarization layer between the third metal layer and the touch structure, and a second planarization layer between the second metal layer and the third metal layer; and
the touch lead further comprises a third lead in the display region, wherein the third lead is electrically connected to the first lead through a via hole penetrating the first planarization layer and the second planarization layer, and the first lead is electrically connected to the second lead through a via hole penetrating the second planarization layer.

3. The display panel according to claim 2, further comprising: a transition region between the display region and the bending region;
wherein the third lead extends to the transition region to be electrically connected to the first lead through the via hole penetrating the first planarization layer and the second planarization layer.

4. The display panel according to claim 3, further comprising: a third planarization layer between the first metal layer and the second metal layer, a high-voltage power line, and a low-voltage power line; wherein
the high-voltage power line comprises a first conductive structure and a second conductive structure in the binding region, the first conductive structure is in the first metal layer, the second conductive structure is in the second metal layer, and the first conductive structure is electrically connected to the second conductive structure through a via hole penetrating the third planarization layer; and
the low-voltage power line comprises a third conductive structure and a fourth conductive structure in the binding region, the third conductive structure is in the first metal layer, the third conductive structure is arranged spaced from the first conductive structure, the fourth conductive structure is in the second metal layer, the fourth conductive structure is arranged spaced from the second conductive structure, and the third conductive structure is electrically connected to the fourth conductive structure through the via hole penetrating the third planarization layer.

5. The display panel according to claim 4, wherein the high-voltage power line further comprises a fifth conductive structure in the binding region, the fifth conductive structure is in the third metal layer, and the fifth conductive structure is electrically connected to the second conductive structure through the via hole penetrating the second planarization layer;
the low-voltage power line further comprises a sixth conductive structure in the binding region, the sixth conductive structure is in the third metal layer, the sixth conductive structure is arranged spaced from the fifth conductive structure, and the sixth conductive structure is electrically connected to the fourth conductive structure through the via hole penetrating the second planarization layer; and
the second lead is insulated from the fifth conductive structure and the sixth conductive structure.

6. The display panel according to claim 5, wherein the sixth conductive structure comprises two conductive sub-structures arranged spaced from each other, and the second lead is located between the two conductive sub-structures.

7. The display panel according to claim 2, wherein the organic insulation layers comprise a first organic insulation layer and a second organic insulation layer that are stacked;
the touch electrode layers comprise a first touch electrode layer between the first organic insulation layer and the second organic insulation layer, and a second touch electrode layer on one side, facing away from the base substrate, of the second organic insulation layer; and
the third lead comprises a first sub-lead and a second sub-lead that are electrically connected to each other, wherein the first sub-lead is in the first touch electrode layer, the second sub-lead is in the second touch electrode layer, and the first sub-lead is electrically connected to the first lead through the via hole penetrating the first planarization layer and the second planarization layer.

8. The display panel according to claim 7, further comprising: a protective layer on one side, facing away from the base substrate, of the second touch electrode layer;
wherein a material of the protective layer is same as a material of the organic insulation layers;
an orthographic projection of the protective layer on the base substrate covers the base substrate; and
the protective layer is in direct contact with the second lead.

9. The display panel according to claim 7, further comprising: a protective layer on one side, facing away from the base substrate, of the second touch electrode layer;
wherein a material of the protective layer is same as a material of the organic insulation layers;
an orthographic projection of the first planarization layer on the base substrate covers the base substrate; and
an orthographic projection of the protective layer on the base substrate does not overlap the orthographic projections of the binding region and the bending region on the base substrate.

10. A display device, comprising: the display panel according to claim 1.

11. The display device according to claim 10, further comprising: a first planarization layer between the third metal layer and the touch structure, and a second planarization layer between the second metal layer and the third metal layer; and
the touch lead further comprises a third lead in the display region, wherein the third lead is electrically connected to the first lead through a via hole penetrating the first planarization layer and the second planarization layer, and the first lead is electrically connected to the second lead through a via hole penetrating the second planarization layer.

12. The display device according to claim 11, further comprising: a transition region between the display region and the bending region;
wherein the third lead extends to the transition region to be electrically connected to the first lead through the via hole penetrating the first planarization layer and the second planarization layer.

13. The display device according to claim 12, further comprising: a third planarization layer between the first metal layer and the second metal layer, a high-voltage power line, and a low-voltage power line; wherein
the high-voltage power line comprises a first conductive structure and a second conductive structure in the binding region, the first conductive structure is in the first metal layer, the second conductive structure is in the second metal layer, and the first conductive structure is electrically connected to the second conductive structure through a via hole penetrating the third planarization layer; and
the low-voltage power line comprises a third conductive structure and a fourth conductive structure in the binding region, the third conductive structure is in the first metal layer, the third conductive structure is arranged spaced from the first conductive structure, the fourth conductive structure is in the second metal layer, the fourth conductive structure is arranged spaced from the second conductive structure, and the third conductive structure is electrically connected to the fourth conductive structure through the via hole penetrating the third planarization layer.

14. The display device according to claim 13, wherein the high-voltage power line further comprises a fifth conductive structure in the binding region, the fifth conductive structure is in the third metal layer, and the fifth conductive structure is electrically connected to the second conductive structure through the via hole penetrating the second planarization layer;
the low-voltage power line further comprises a sixth conductive structure in the binding region, the sixth conductive structure is in the third metal layer, the sixth conductive structure is arranged spaced from the fifth conductive structure, and the sixth conductive structure is electrically connected to the fourth conductive structure through the via hole penetrating the second planarization layer; and
the second lead is insulated from the fifth conductive structure and the sixth conductive structure.

15. The display device according to claim 14, wherein the sixth conductive structure comprises two conductive sub-structures arranged spaced from each other, and the second lead is located between the two conductive sub-structures.

16. The display device according to claim 11, wherein the organic insulation layers comprise a first organic insulation layer and a second organic insulation layer that are stacked;
the touch electrode layers comprise a first touch electrode layer between the first organic insulation layer and the second organic insulation layer, and a second touch electrode layer on one side, facing away from the base substrate, of the second organic insulation layer; and
the third lead comprises a first sub-lead and a second sub-lead that are electrically connected to each other, wherein the first sub-lead is in the first touch electrode layer, the second sub-lead is in the second touch electrode layer, and the first sub-lead is electrically connected to the first lead through the via hole penetrating the first planarization layer and the second planarization layer.

17. The display device according to claim 16, further comprising: a protective layer on one side, facing away from the base substrate, of the second touch electrode layer;
wherein a material of the protective layer is same as a material of the organic insulation layers;
an orthographic projection of the protective layer on the base substrate covers the base substrate; and
the protective layer is in direct contact with the second lead.

18. The display device according to claim 16, further comprising: a protective layer on one side, facing away from the base substrate, of the second touch electrode layer;
wherein a material of the protective layer is same as a material of the organic insulation layers;
an orthographic projection of the first planarization layer on the base substrate covers the base substrate; and
an orthographic projection of the protective layer on the base substrate does not overlap the orthographic projections of the binding region and the bending region on the base substrate.
